(19) United States
(12) Patent Application Publication
(10) Pub. No.: US 2010/0163951 A1
(43) Pub. Date: Jul. 1, 2010

(54) FLASH MEMORY DEVICE AND MANUFACTURING METHOD OF THE SAME

(76) Inventor: Cheon Man Shim, Seoul (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/616,532

(22) Filed: Nov. 11, 2009

(30) Foreign Application Priority Data
Dec. 31, 2008 (KR) 10-2008-0138884

(51) Int. Cl. H01L 29/78; H01L 21/76; H01L 21/336

(52) U.S. Cl. 257/314; 438/294; 257/E29.255; 257/E21.54; 257/E21.409

(57) ABSTRACT

A flash memory device is disclosed including: a device isolation layer and an active area formed on a semiconductor substrate in which a source plate and a bit line area are defined; a memory gate formed over the active area of the bit line area; a control gate formed on the semiconductor substrate including the memory gate; a common source area and a drain area disposed on both sides of the control gate; and a common source line contact formed over the common source area of the semiconductor substrate at the active area of the source plate, wherein the active area of the source plate is formed having the same interval with the active area of the bit line area, and the control gate is formed to cross the source plate and the bit line area disposed at both sides of the source plate.

### CROSS-REFERENCE TO RELATED APPLICATION

This application claims the benefit under 35 U.S.C. §119 to Korean Patent Application No. 10-2008-0138884, filed Dec. 31, 2008, which is hereby incorporated by reference in its entirety.

### BACKGROUND

A flash memory device is a nonvolatile memory medium in which stored data is not damaged even though power supply is turned off, and has an advantage in that the speed of data processing such as recording, reading, and deleting, etc., is relatively high.

Accordingly, the flash memory device is widely used for a Bios of a personal computer (PC), and for storing data of a set-top box, printer, and network server, etc., and is lately broadly used in digital cameras and cellular phones.

In the flash memory device, a stack gate type semiconductor device using a floating gate and a semiconductor device in a silicon-oxide-nitride-oxide-silicon (SONOS) structure are used.

The flash memory device can obtain competitiveness (area-wise) only when unit cells are concentrated on a narrow area so that a common source line is formed rather than a contact on each of the sources.

At this time, because the common source line is formed to be larger than a bit line, this difference in size affects the process when forming adjacent bit lines due to lines having irregular sizes, which results in a difficulty in forming a uniform pattern.

Moreover, a control gate is formed bent in an area where the common source line contact is formed, which may cause a bridge with a neighbored control gate.

Furthermore, a word line contact is formed only at opposite ends of the long control gate to generate voltage drop in the control gate when an erase operation is performed. Therefore, the same erase operation may not be operated.

### BRIEF SUMMARY

An embodiment provides a flash memory device and a manufacturing method of the same.

A flash memory device according to an embodiment includes: a device isolation layer and an active area formed on a semiconductor substrate in which a source plate and a bit line area are defined; a memory gate formed over the active area of the bit line area; a control gate formed on the semiconductor substrate including the memory gate; a common source area and a drain area disposed at both sides of the control gate, the common source area and the drain area crossing the active area; and a common source line contact formed over the common source area of the semiconductor substrate at the active area of the source plate, wherein the active area of the source plate is formed having the same interval with the active area of the bit line area, and wherein the control gate is formed to cross the source plate and the bit line area disposed at both sides of the source plate.

### BRIEF DESCRIPTION OF THE DRAWINGS

FIGS. 1 to 3 are process plan views of a flash memory device according to an embodiment.

FIGS. 4A and 4B are cross-sectional views respectively taken along lines X-X′ and Y-Y′ of FIG. 3.

### DETAILED DESCRIPTION

Hereinafter, embodiments will be described with reference to the accompanying drawings.

In the description of embodiments, when an element is referred to as being “on/under” another element, it can be directly on/under the other element or be indirectly on the other element with one or more intervening elements interposed therebetween. Also, the reference for “on/under” each layer will be described based on the drawings.

In the drawings, the thickness or size of each layer may be exaggerated, omitted or schematically illustrated for the convenience and clarity of explanation. Also, the size of each constituent does not completely reflect its actual size.

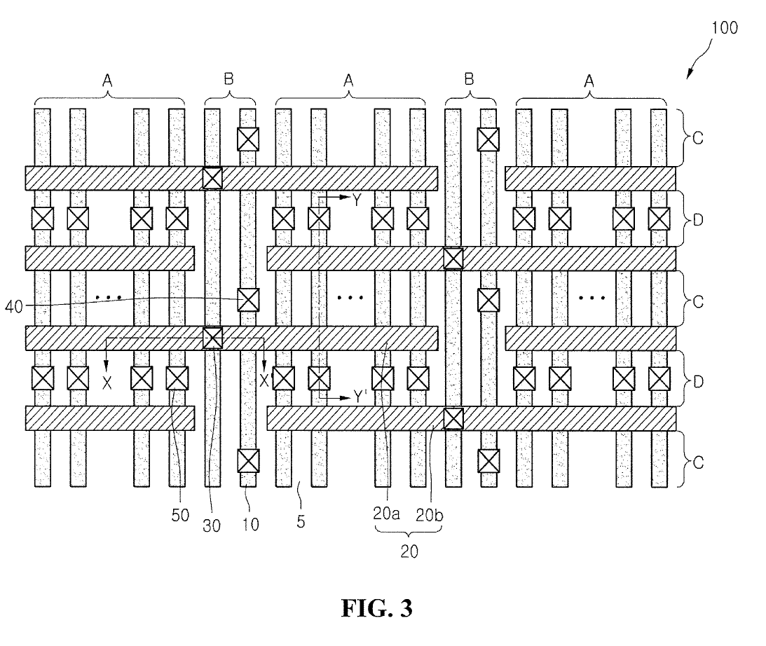

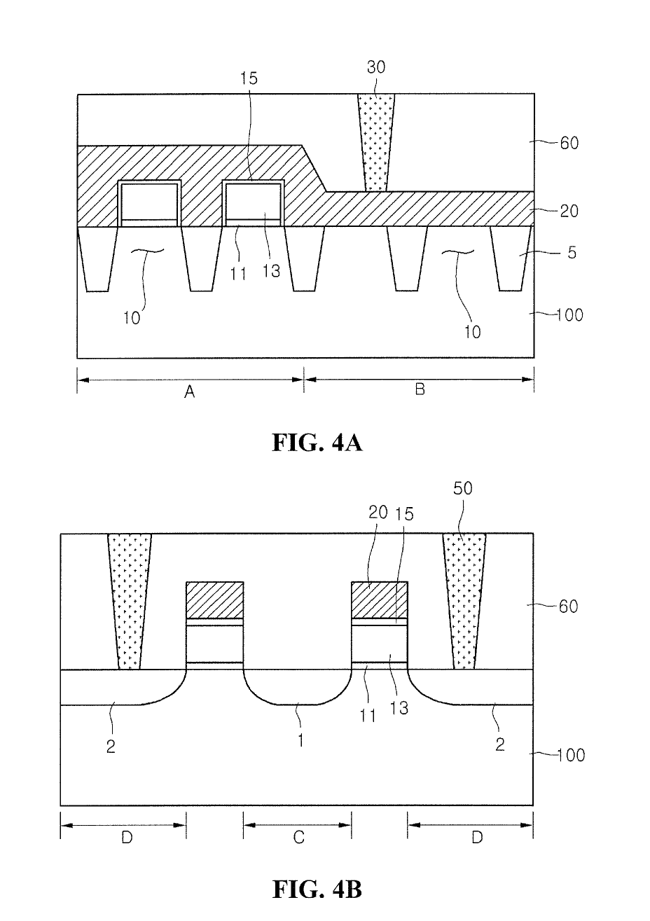

FIG. 3 shows a flash memory device according to an embodiment and FIGS. 4A and 4B show cross-sectional views taken along lines X-X′ and Y-Y′, respectively, of FIG. 3.

As shown in FIGS. 3, 4A and 4B, the flash memory device in accordance with an embodiment includes: a device isolation layer 5 and an active area 10 formed on a semiconductor substrate 100 in which a source plate B and a bit line area A are defined; a memory gate (see e.g. reference 15 FIG. 4A) formed over the active area of the bit line area A; a control gate 20 formed on the semiconductor substrate 100 including the memory gate; a common source area C and a drain area D disposed at opposite sides of the control gate 20, the common source area C and the drain area D crossing the active area 10; and a common source line contact 40 formed over the common source area C of the semiconductor substrate 100 at source plate B, wherein the active area of the source plate B is formed having the same interval with the active area of the bit line area A, and wherein the control gate 20 is formed to cross the source plate B and the bit line area A disposed at both sides of the source plate B.

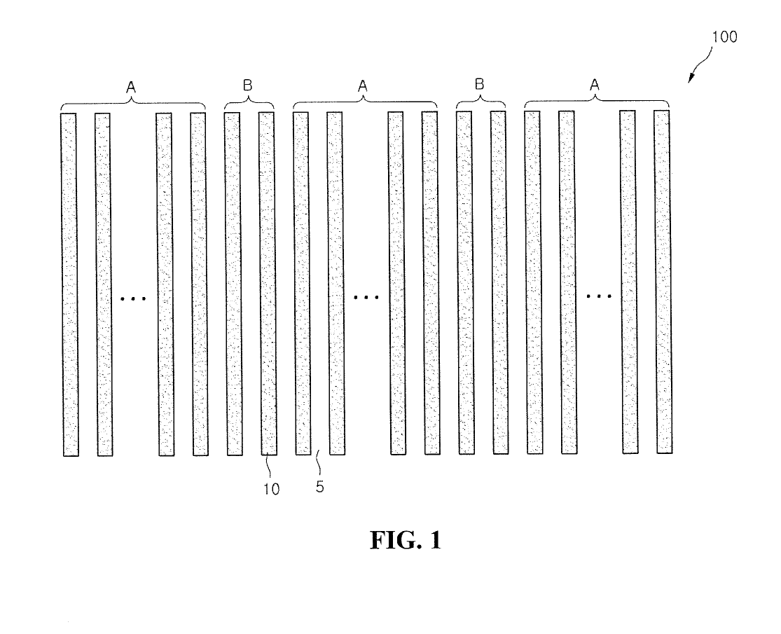

Hereinafter, a manufacturing method of a flash memory device will be described with reference to FIGS. 1 to 4.

FIGS. 1 to 3 are process plan views of the flash memory device according to an embodiment.

As shown in FIG. 1, an active area 10 is defined by forming a device isolation layer 5 on a semiconductor substrate 100.

The device isolation layer 5 may be formed by forming a trench in the semiconductor substrate 100 and then burying dielectric material therein.

At this time, a source plate B, which is the active area 10 where a common source line contact is formed, may be formed having the same interval with the active area 10 of a bit line area A.

The active area of the source plate B and the active area of the bit line area A have the same interval, making it possible to simply manufacture a mask and to easily bury dielectric material for forming the device isolation layer.

The bit line area A is formed by repeating a plurality of active areas 10. The device layout has a structure where the source plate B is disposed between different bit line areas A such that the source plates and the bit line areas alternate.

And, although not shown, after forming the device isolation layer 5 that defines the active area 10, a memory gate may be formed by forming a tunnel oxide layer and a floating gate on the semiconductor substrate 100 at the bit line area A (see e.g. references 11 and 13 of FIG. 4A).

In the case of a stack gate type memory gate, a floating gate formed of polysilicon may be formed.

However, the memory gate is not limited thereto. F or example, the memory gate may be formed in a silicon-oxide-nitride-oxide-silicon (SONOS) type memory structure.

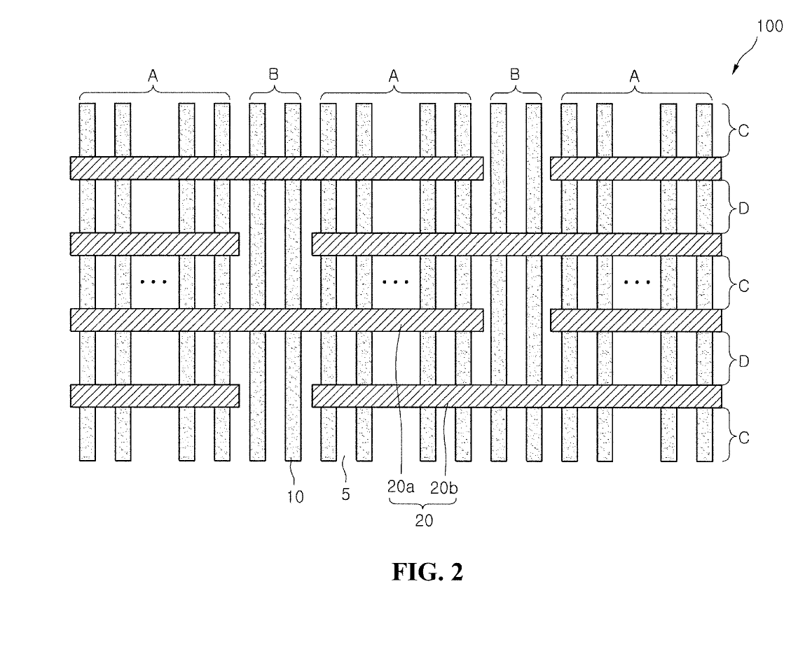

Continuously, as shown in FIG. 2, a control gate 20 is formed on the semiconductor substrate 100 on which the memory gate is formed, and an ion implantation process is processed thereon to form a common source area C and a drain area D on the semiconductor substrate 100.

The control gate 20 may be formed of polysilicon and may be formed to be intersected over the active area 10.

The control gate 20 is formed to cross different bit line areas A disposed on the two sides of the source plate B while centering on the source plate B.

In other words, the control gate 20 is formed to cross two bit line areas A for one source plate B, wherein the control gate 20 may be formed in plural in the direction of the word lines.

At this time, different control gates 20 formed for the same word line are formed to be separated from each other by another source plate B. For example, as shown in the top row of FIG. 2, two control gates 20 are separated at a source plate B.

In addition, the control gates 20 are separated from each other centering on the drain area D or the common source area C to be parallel to each other, wherein neighbored control gates 20 may be formed to be overlapped with one bit line area A of two bit line areas A.

In other words, a first control gate 20a and a second control gate 20b are formed to be parallel to each other centering on the drain area D or the common source area C and to be overlapped at one bit line area A. For example, as shown in FIG. 2, the first control gate 20a and the second control gate 20b overlap the central bit line area A.

Moreover, in contrast to a related art where the control gate 20 is formed be bent in the area where the common source line contact is formed, in the present embodiment, the control gate 20 is formed in a straight line shape intersected with the bit line area A and the source plate B, instead of being bent.

In other words, the control gate 20 is formed in a straight line shape, not being bent, making it possible to inhibit a generation of a bridge with the neighbored control gate. In addition, the control gate 20 is formed having a uniform line width, making it possible to obtain uniform cell characteristics.

Continuously, as shown in FIG. 3, a common source line contact 40 and a word line contact 30 are formed on the source plate B of the semiconductor substrate 100, and a drain contact 50 is formed on the bit line area A of the semiconductor substrate 100.

The common source line contact 40, the word line contact 30, and the drain contact 50 may be formed by forming an interlayer dielectric layer on the semiconductor substrate 100 and then performing a contact forming process thereon.

The word line contact 30 may be formed on any one of the active areas 10 of the source plate B intersected with the control gate 20 such that the word line contact 30 is connected to and contacts the control gate 20.

The common source line contact 40 is formed over the active area 10 where the source plate B is intersected with the common source area C.

At this time, the common source line contact 40 may be formed in an active area other than the active area 10 of the source plate B near where the word line contact 30 for the control gate 20 is formed.

In other words, the common source line contact 40 and the word line contact 30 are formed over the source plate B, wherein they may be formed over different active areas 10.

And, the word line contacts 30 may be formed for each control gate 20.

In other words, a plurality of control gates 20 that can each control two bit line areas A are formed along one word line, and the word line contacts 30 are formed on each of the plurality of control gates 20.

At this time, the control gates 20 that are neighbored to each other in parallel are overlappedly formed only on one bit line area A so that the word line contact 30 formed on the control gates 20 is formed on the control gate 20 overlapping a different source plate B from the word line contact formed on the control gates that are neighbored to each other in parallel.

In other words, the word line contact 30 formed on the first control gate 20a and the word line contact 30 formed on the second control gate 20b are positioned on different source plates B.

The drain contact 50 is formed over the bit line area A intersected with the drain area D.

And, although not shown, the common source line contact 40 and the word line contact 30 may be connected to a metal wiring of a metal wiring layer to be formed later.

In other words, the word line contact 30 is connected to an upper metal wiring to simultaneously apply voltage to all of the control gates 20 positioned on the same word line so that voltage can be applied without voltage drop in the control gate 20, making it possible to erase cells in a sector with the same bias.

FIGS. 4A and 4B are cross-sectional views taken along lines X-X′ and Y-Y′, respectively, of FIG. 3.

FIG. 4A is a cross-sectional view taken along line X-X′ of FIG. 3. As shown in FIG. 4A, the device isolation layer 5 is formed on the semiconductor substrate 100 in which the bit line area A and the source plate B are defined. The active areas 10 are the regions between the device isolation layer 5.

A tunnel oxide layer 11, a floating gate 13, a dielectric layer 15, and a control gate 20 are formed over the bit line area A. An interlayer dielectric layer 60 is formed over the semiconductor substrate 100 and a word line contact 30 is formed on the control gate 20 over an active area of the source plate B.

FIG. 4B is a cross-sectional view taken along line Y-Y′ of FIG. 3. As shown in FIG. 4B, the tunnel oxide layer 11, the floating gate 13, the dielectric layer 15, and the control gate 20 are formed on the semiconductor substrate 100.

A first impurity area 1 is formed in the common source area C and a second impurity area 2 is formed in the drain area D.

The dielectric layer 15 may be formed of an oxide-nitride-oxide (ONO) layer, and the floating gate 13 and the control gate 20 may be formed of polysilicon.

A drain contact 50 formed in the interlayer dielectric layer 60 is formed contacting the drain area D.

With the manufacturing method of the flash memory device according to the embodiment as described above, the source plate where the source contact is formed is also formed with active areas having the same interval as the bit line area, making it possible to reduce fluctuation width of the bit line adjacent to the source plate.

Moreover, the control gate is formed in a straight line shape not being bent, making it possible to inhibit the bridge with the control gate from being generated. In addition, the control gate is formed having a uniform line width, making it possible to obtain uniform cell characteristics.

Furthermore, the word line contact is connected to the upper metal wiring to apply voltage to all control gates simultaneously so that the voltage can be applied without voltage drop in the control gates, making it possible to stabilize the characteristics of the memory device.

In addition, the active area of the source plate and the active area of the bit line area have the same interval, making it possible to simply manufacture a mask and to easily gap-fill the dielectric material for forming the device isolation layer.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A flash memory device comprising:
a device isolation layer and an active area formed on a semiconductor substrate in which a source plate and a bit line area are defined;
a memory gate formed over the active area of the bit line area;
a control gate formed on the semiconductor substrate including the memory gate;
a common source area and a drain area disposed at respective sides of the control gate, the common source area and the drain area crossing the active area; and
a common source line contact formed over the common source area of the semiconductor substrate at the active area of the source plate,
wherein the active area of the source plate is formed having the same interval with the active area of the bit line area, and wherein the control gate is formed to cross the source plate and the bit line area disposed at both sides of the source plate.

2. The flash memory device according to claim 1, wherein the source plate comprises at least two active areas, and wherein the control gate crosses the at least two active areas, the flash memory device further comprising:
a word line contact formed contacting the control gate over one active area of the source plate.

3. The flash memory device according to claim 2, wherein the common source line contact is formed on the active area of the at least two active areas where the source plate is intersected with the common source area, the common source line contact being formed over a different active area from the one active area of the source plate where the word line contact is formed.

4. The flash memory device according to claim 3, wherein the control gate is formed in plurality along a same word line, the flash memory device further comprising:
a metal wiring formed on the word line contact for simultaneous application of a voltage to all of the control gates positioned along the same word line.

5. The flash memory device according to claim 1, wherein the control gate is formed in plurality according to word lines, wherein the control gates are disposed in parallel and separated by the common source area and the drain area, wherein neighboring parallel control gates overlap only one same bit line area while each crossing one source plate and two bit line areas.

6. The flash memory device according to claim 1, wherein the control gate is formed in plurality along a single world line direction, the flash memory device further comprising a word line contact formed on each of the plurality of control gates formed along the single word line direction.

7. A manufacturing method of a flash memory device, comprising:
defining an active area by forming a device isolation layer on a semiconductor substrate in which a source plate and a bit line area are defined;
forming a memory gate over the active area of the bit line area;
forming a control gate on the semiconductor substrate including the memory gate;
forming a common source area and a drain area on the semiconductor substrate at respective sides of the control gate, the common source area and the drain area crossing the active area; and
forming a common source line contact over the common source area of the semiconductor substrate at the active area of the source plate,
wherein the active area of the source plate is formed having the same interval with the active area of the bit line area, and wherein the control gate is formed to cross the source plate and the bit line area disposed at both sides of the source plate.

8. The manufacturing method of the flash memory device according to claim 7, wherein the source plate comprises at least two active areas, and wherein the control gate crosses the at least two active areas, the manufacturing method further comprising:
forming a word line contact contacting the control gate over one active area of the source plate.

9. The manufacturing method of the flash memory device according to claim 8, wherein the common source line contact is formed on the active area of the at least two active areas where the source plate is intersected with the common source area, the common source line contact being formed over a different active area from the one active area of the source plate where the word line contact is formed.

10. The manufacturing method of the flash memory device according to claim 9, wherein the control gate is formed in plurality along a same word line, the manufacturing method further comprising:
forming a metal wiring on the word line contact for simultaneous application of a voltage to all of the control gates positioned on the same word line.

11. The manufacturing method of the flash memory device according to claim 7, wherein forming the control gate comprises forming the control gate in plurality according to word lines such that the control gates are disposed in parallel and separated by the common source area and the drain area, wherein neighboring parallel control gates overlap only one same bit line area while each crossing one source plate and two bit line areas.

12. The manufacturing method of the flash memory device according to claim 7, wherein the control gate is formed in plurality along a single world line direction, the manufacturing method further comprising:
forming a word line contact on each of the plurality of control gates formed along the single word line direction.
